(19) United States
(12) Patent Application Publication
(10) Pub. No.: US 2022/0037258 A1
(43) Pub. Date: Feb. 3, 2022

(54) SEMICONDUCTOR DEVICES WITH THERMAL BUFFER STRUCTURES

(71) Applicant: Micron Technology, Inc., Boise, ID (US)

(72) Inventor: Shams U. Arifeen, Boise, ID (US)

(21) Appl. No.: 16/941,437

(22) Filed: Jul. 28, 2020

(51) Int. Cl. H01L 23/538; H01L 23/367; H01L 21/768

(52) U.S. Cl. CPC H01L 23/5389; H01L 21/76805; H01L 23/3672

(57) ABSTRACT

Semiconductor devices including structures for thermal management, and associated systems and methods, are described herein. In some embodiments, a semiconductor device includes a first die assembly including a semiconductor substrate and a plurality of active circuit elements at a first surface of the semiconductor substrate. The device also includes a second die assembly including a carrier substrate and a redistribution structure on or over a first surface of the carrier substrate. The device further includes a thermal buffer structure between the first and second die assemblies, the thermal buffer structure being coupled to a second surface of the semiconductor substrate and a second surface of the carrier substrate. The device also includes a plurality of interconnections extending through at least the semiconductor substrate, the carrier substrate, and the thermal buffer structure to electrically couple the active circuit elements to the redistribution structure.

### TECHNICAL FIELD

The present technology generally relates to semiconductor devices, and more particularly relates to techniques for managing heat in semiconductor devices.

### BACKGROUND

Packaged semiconductor dies, including memory chips, microprocessor chips, and imager chips, typically include a semiconductor die mounted on a substrate and encased in a protective covering. The semiconductor die can include functional features, such as memory cells, processor circuits, and imager devices, as well as bond pads electrically connected to the functional features. The bond pads can be electrically connected to terminals outside the protective covering to allow the semiconductor die to be connected to higher level circuitry.

Memory devices are widely used to store information related to various electronic devices such as computers, wireless communication devices, cameras, digital displays, and the like. Memory devices are frequently provided as internal, semiconductor, integrated circuits and/or external removable devices in computers or other electronic devices. Market pressures continually drive semiconductor manufacturers to develop high speed memory devices with faster data rates. However, faster data rates typically involve higher current through the metal interconnections within the device, which produces Joule heating and increases the temperature within the device. Higher temperatures may detrimentally affect device performance and reliability, and may also increase yield loss during manufacturing.

### BRIEF DESCRIPTION OF THE DRAWINGS

Many aspects of the present technology can be better understood with reference to the following drawings. The components in the drawings are not necessarily to scale. Instead, emphasis is placed on illustrating clearly the principles of the present technology.

FIG. 1 is a side cross-sectional view of a semiconductor device.

FIG. 2A is a schematic side cross-sectional view of a semiconductor device with a thermal buffer structure configured in accordance with embodiments of the present technology.

FIG. 2B is a schematic side cross-sectional view of a first die assembly of the device of FIG. 2A during a manufacturing process, in accordance with embodiments of the present technology.

FIG. 2C is a schematic side cross-sectional view of a second die assembly of the device of FIG. 2A during a manufacturing process, in accordance with embodiments of the present technology.

FIG. 3A is a schematic side cross-sectional view of a semiconductor device with a thermal buffer structure configured in accordance with embodiments of the present technology.

FIG. 3B is a schematic side cross-sectional view of a first die assembly of the device of FIG. 3A during a manufacturing process, in accordance with embodiments of the present technology.

FIG. 3C is a schematic side cross-sectional view of a second die assembly of the device of FIG. 3A during a manufacturing process, in accordance with embodiments of the present technology.

FIG. 4A is a schematic side cross-sectional view of a semiconductor device with a thermal buffer structure configured in accordance with embodiments of the present technology.

FIG. 4B is a schematic side cross-sectional view of a die assembly of the device of FIG. 4A after a stage of a manufacturing process, in accordance with embodiments of the present technology.

FIG. 4C is a schematic side cross-sectional view of the device of FIG. 4A after a subsequent stage of the manufacturing process, in accordance with embodiments of the present technology.

FIG. 5 is a schematic side cross-sectional view of a semiconductor package configured in accordance with embodiments of the present technology.

FIG. 6 is a schematic side cross-sectional view of a semiconductor package configured in accordance with embodiments of the present technology.

FIG. 7 is a schematic side cross-sectional view of a semiconductor package configured in accordance with embodiments of the present technology.

FIG. 8 is a schematic side cross-sectional view of a semiconductor package configured in accordance with embodiments of the present technology.

FIG. 9 is a schematic side cross-sectional view of a semiconductor package configured in accordance with embodiments of the present technology.

FIG. 10 is a schematic view of a system that includes a semiconductor device or package configured in accordance with embodiments of the present technology.

### DETAILED DESCRIPTION

Specific details of several embodiments of semiconductor devices, and associated systems and methods, are described below. In some embodiments, for example, a semiconductor device configured in accordance with the present technology includes a semiconductor substrate including a first (e.g., front) surface and a second (e.g., back) surface opposite the first surface, and a plurality of active circuit elements (e.g., transistors) at the first surface of the semiconductor substrate. The device can also include a redistribution structure including a plurality of conductive components (e.g., metal layers, traces, vias, etc.) for routing signals to and from the active circuit elements. The redistribution structure can be separated from the active circuit elements and the semiconductor substrate by a thermal buffer structure coupled to the second surface of the semiconductor substrate. For example, the redistributions structure can be located on or over a carrier substrate attached to the thermal buffer structure, or can be located on or over the thermal buffer structure itself. To allow for signal transmission across the device, the active circuit elements can be electrically coupled to the redistribution structure by a plurality of interconnections (e.g., vias, pillars, micro-bumps, etc.) extending through the semiconductor substrate, the thermal buffer structure, and the carrier substrate (if present). The thermal buffer structure physically separates and thermally isolates the redistribution structure from the active circuit elements, which may reduce or prevent heat generated in the redistribution structure (e.g., by Joule heating) from being transmitted to the active circuit elements. Accordingly, the present technology can improve the performance and reliability of semiconductor devices, and can also reduce yield loss during device manufacturing and testing.

In some embodiments, the present technology provides improved memory devices in which a thermal buffer structure is used to reduce or prevent heating of temperature-sensitive components (e.g., CMOS circuitry). Memory devices configured in accordance with embodiments of the present technology can include volatile memory devices (e.g., static random access memory (SRAM), dynamic random access memory (DRAM), synchronous dynamic random access memory (SDRAM), etc.) as well as non-volatile memory (e.g., flash memory (e.g., NAND, NOR), phase change memory (PCM), ferroelectric random access memory (FeRAM), resistive random access memory (RRAM), and magnetic random access memory (MRAM), etc.). For example, the present technology can include memory devices (e.g., NAND, DRAM, NOR, etc.) in which the CMOS circuitry and memory array are separated from the redistribution structure by a thermal buffer structure, or in which the CMOS circuitry is separated from both the memory array and the redistribution structure by the thermal buffer structure. CMOS circuitry can include, for example, high speed and/or high power devices, such as drivers, sense amplifiers, data latches, input/output devices, and the like. CMOS circuitry may exclude memory array devices such as access transistors, array charge storage elements, and the like. In other embodiments, however, the present technology can be implemented in other types of memory devices, or in other types of semiconductor devices (e.g., logic devices, controller devices, etc.).

A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

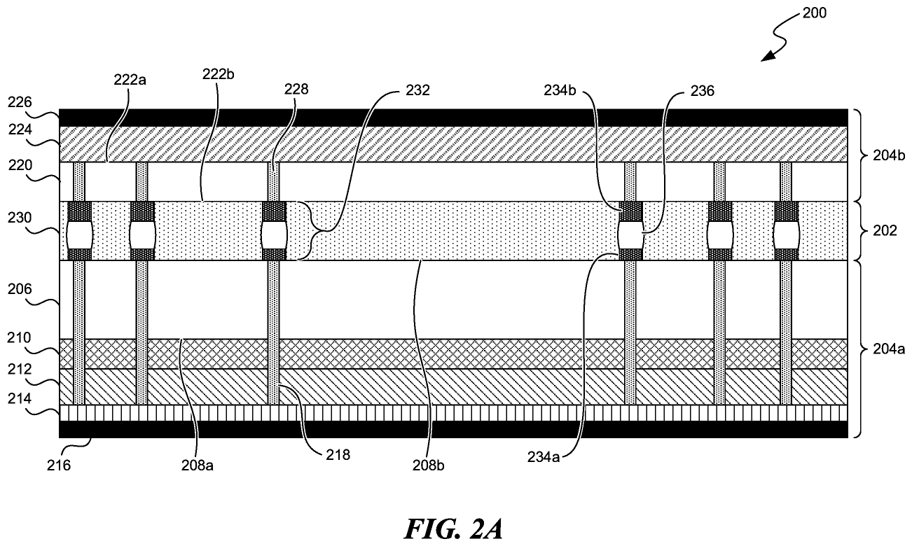

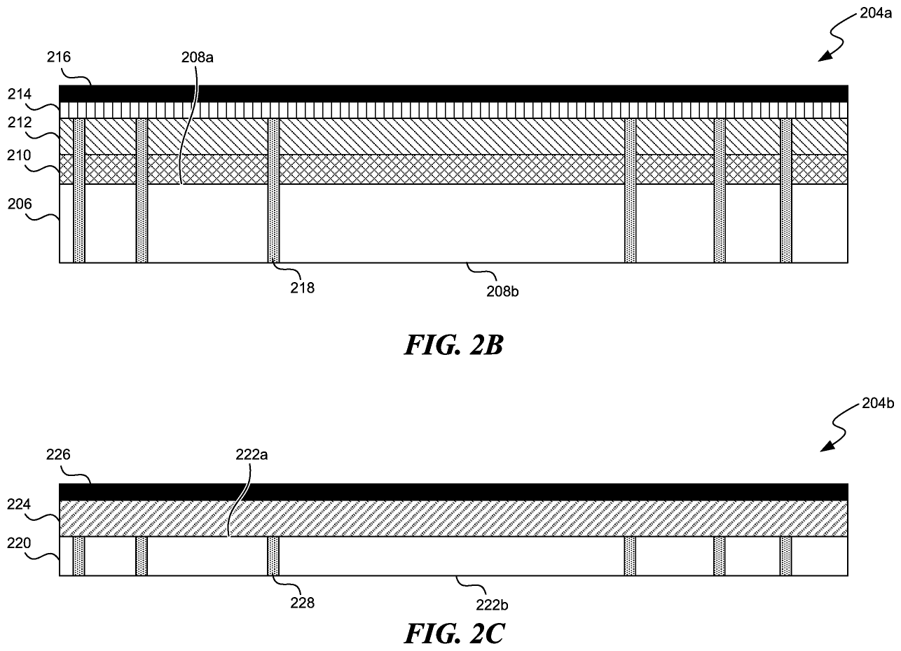

Numerous specific details are disclosed herein to provide a thorough and enabling description of embodiments of the present technology. A person skilled in the art, however, will understand that the technology may have additional embodiments and that the technology may be practiced without several of the details of the embodiments described below with reference to FIGS. 2A-10. For example, some details of semiconductor devices and/or packages well known in the art have been omitted so as not to obscure the present technology. In general, it should be understood that various other devices and systems in addition to those specific embodiments disclosed herein may be within the scope of the present technology.

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

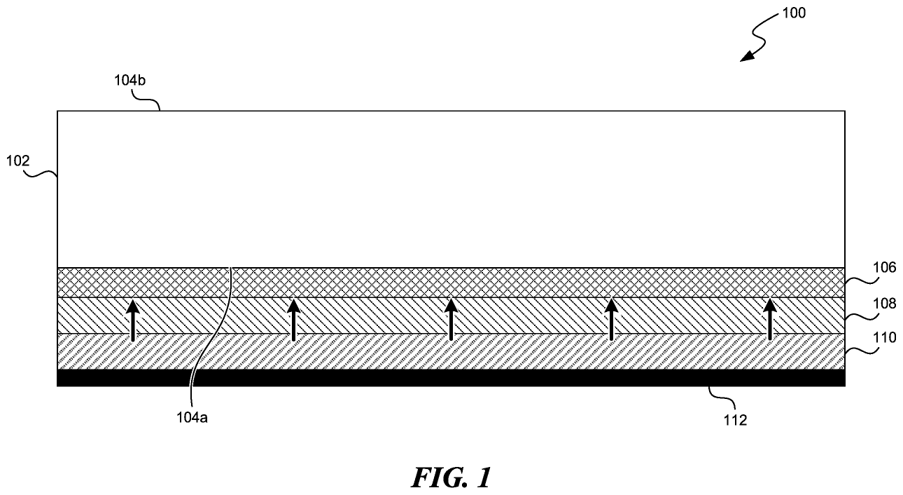

FIG. 1 is a schematic side cross-sectional view of a semiconductor device 100. The device 100 includes a semiconductor substrate 102 having a first surface 104a and a second surface 104b. A plurality of active circuit elements 106 (e.g., transistors and/or other front-end-of-line (FEOL) elements) are formed on and/or in the first surface 104a. The device 100 also includes an intermediate structure 108 (e.g., a middle-of-line (MOL) structure) such as a memory array, a redistribution structure 110 (e.g., a back-end-of-line (BEOL) structure), and a thermal and/or electrical insulating material 112. During operation of the device 100, heat is generated in the redistribution structure 110 and/or the intermediate structure 108, e.g., due to Joule heating of metallic interconnections within these components. In some embodiments, the redistribution structure 110 has thicker metallic interconnections than the intermediate structure 108, and thus produces the majority of the heat. Because the redistribution structure 110 and intermediate structure 108 are in close proximity to the active circuit elements 106, the heat generated in the redistribution structure 110 and/or the intermediate structure 108 is transmitted directly to the active circuit elements 106 via conduction (e.g., as indicated by the vertical arrows in FIG. 1). This increases the operating temperature of the active circuit elements 106, which can detrimentally affect performance. For example, in embodiments where the device 100 is a memory die, excessively high temperatures from the redistribution structure 110 and/or the intermediate structure 108 degrades device reliability (e.g., loss of data retention) and/or performance (e.g., reduced data rates), as well as yield loss during device manufacturing and testing.

FIG. 2A is a schematic side cross-sectional view of a semiconductor device 200 with a thermal buffer structure 202 configured in accordance with embodiments of the present technology. The device 200 includes a first die assembly 204a and a second die assembly 204b connected to each other by the thermal buffer structure 202. As described in greater detail below, the thermal buffer structure 202 can thermally isolate the first die assembly 204a from the second die assembly 204b. In some embodiments, the first die assembly 204a includes one or more first components that are sensitive to high temperatures (e.g., CMOS circuitry and/or other FEOL elements), while the second die assembly 204b includes one or more second components that generate heat during operation (e.g., redistribution structures and/or other BEOL elements), or vice-versa. For example, the first components can have a temperature threshold at which performance is impaired or (“first component threshold temperature”), and the second components can have an operating temperature (“second component operating temperature”) above the threshold temperature. The thermal buffer structure 202 can be configured to reduce or inhibit transfer of heat from the second die assembly 204b to the first die assembly 204a (or vice-versa) to mitigate heating of the temperature-sensitive first components. For example, the amount of heat transferred from the second die assembly 204b to the first die assembly 204a can be no more than 90%, 80%, 70%, 60%, 50%, 40%, 30%, 20%, 10%, or 5% of the total heat generated in the second die assembly 204a.

In some embodiments, the second die assembly 204b includes all of the components of the device 200 that are expected to generate significant amounts of heat during operation of the device (e.g., redistribution structures and/or other BEOL elements), and the first die assembly 204a includes all of the components that are expected to be substantially impaired by high operating temperatures (e.g., CMOS circuitry and/or other FEOL elements). Accordingly, the first die assembly 204a may lack any components that are expected to significantly increase the temperature of the device 200 during operation, while the second die assembly 204b may lack any components that are detrimentally affected by high operating temperatures. In some embodiments, at least 50%, 60%, 70%, 80%, 90%, 95%, or 99% of the total heat generated by the device 200 during operation originates from the second die assembly 204b, while less than 50%, 40%, 30%, 20%, 10%, 5%, or 1% of the total heat generated by the device 200 during operation originates from the first die assembly 204a.

The first components of the first die assembly 204a can include the active semiconductor components of the device 200. As shown in FIG. 2A, the first die assembly 204a includes a semiconductor substrate 206 having a first surface 208a (e.g., a front or active surface) and a second surface 208b (e.g., a back surface) opposite the first surface 208a. The first components of the first die assembly 204a can be active circuit elements 210 formed on the first surface 208a. For example, the active circuit elements 210 can include transistors and/or other FEOL elements (e.g., CMOS circuitry). In some embodiments, the active circuit elements 210 do not include any MOL elements (e.g., memory array devices) or BEOL elements (e.g., redistribution structures). The semiconductor substrate 206 can be any suitable substrate for semiconductor fabrication and processing, such as a silicon substrate, a gallium arsenide substrate, an organic laminate substrate, etc. The thickness of the semiconductor substrate 206 can be varied as desired, e.g., within a range from 5 μm to 700 μm.

In some embodiments, the first die assembly 204a also includes an intermediate structure 212 coupled to the active circuit elements 210. The intermediate structure 212 can include a plurality of MOL components. For example, in embodiments where the device 200 is a memory device, the intermediate structure 212 can include memory components such as a memory array including a plurality of memory cells or circuits (e.g., NAND, NOR, DRAM, etc.), word lines, bit lines, etc. The intermediate structure 212 may not include any FEOL elements (e.g., CMOS circuitry) or BEOL elements (e.g., redistribution structures). In other embodiments, however, the intermediate structure 212 is optional and can be omitted.

The first die assembly 204a can further include a routing structure 214 configured to route signals from the active circuit elements 210 and/or the intermediate structure 212 (if present) to other internal components of the device 200. The routing structure 214 can be coupled to the intermediate structure 212, or can be coupled directly to the active circuit elements 210 if the intermediate structure 212 is omitted. The routing structure 214 can include electrically conductive components such as contacts, lines, traces, wiring, vias, interconnects, etc. In some embodiments, the routing structure 214 is or includes a single metal layer (e.g., a M1 layer). Alternatively, in embodiments where the routing structure 214 includes multiple metal layers, the number of layers can be relatively small (e.g., no more than five, four, three, or two layers). In other embodiments, however, the routing structure 214 is optional and can be omitted entirely.

A first insulating material 216 (e.g., an electrically insulating material) can be coupled to the routing structure 214 to protect the routing structure 214, intermediate structure 212, and active circuit elements 210 from damage (e.g., during manufacturing, packaging, and/or usage of the device 200). The first insulating material 216 can be a passivation material, such as a dielectric material, a polyimide material, and/or other materials used to cover a surface of a semiconductor device.

The first die assembly 204a further includes a first set of vias or interconnections 218 (“first vias 218”) extending from the routing structure 214 to the second surface 208b of the semiconductor substrate 206. The first vias 218 can include through-silicon vias (TSVs) and/or any other suitable type of electrically conductive interconnection. As shown in FIG. 2A, the first vias 218 can extend through the entire thickness of the semiconductor substrate 206, active circuit elements 210, and intermediate structure 212. The first vias 218 can be used to transmit signals between the first die assembly 204a and the second die assembly 204b, as discussed further below.

The second components of the second die assembly 204b can include metallization structures for routing signals between the first die assembly 204a and an external device (e.g., another semiconductor device and/or a package substrate; not shown in FIG. 2A). The second die assembly 204b may lack any FEOL elements or MOL elements. In the illustrated embodiment, the second die assembly 204b includes a carrier substrate 220 (e.g., a silicon, glass, or ceramic substrate or interposer) having a first surface 222a (e.g., a front surface) and a second surface 222b (e.g., a back surface) opposite the first surface 222a. In some embodiments, the carrier substrate 220 does not include any transistors and/or other active circuit elements formed in either the first surface 222a or the second surface 22b. The carrier substrate 220 can have any suitable thickness, such as a thickness within a range from 5 μm to 700 μm. In the illustrated embodiment, the carrier substrate 220 is thinner than the semiconductor substrate 206. For example, the thickness of the carrier substrate 220 can be 90%, 80%, 70%, 60%, 50%, 40%, 30%, 20%, or 10% of the thickness of the semiconductor substrate 206. In other embodiments, however, the thickness of the carrier substrate 220 can be greater than or equal to the thickness of the semiconductor substrate 206.

A redistribution structure 224 is formed on and/or coupled to the first surface 222a of the carrier substrate 220. The redistribution structure 224 can be or include a redistribution layer (RDL) (e.g., formed after a wafer probe test) or an in-line redistribution layer (iRDL) (e.g., formed before a wafer probe test). In some embodiments, the redistribution structure 242 is a BEOL structure including electrically conductive components for routing signals, such as contacts, lines, traces, wiring, vias, interconnects, etc. The redistribution structure 224 can also include bond pads (not shown) for electrically coupling the device 200 to an external device (not shown) such as another semiconductor device or a package substrate, as discussed further below.

In some embodiments, the redistribution structure 224 includes a plurality of metal layers (e.g., M2-M4 layers). The redistribution structure 224 can include more metal layers than the routing structure 214 of the first die assembly 204a. For example, the routing structure 214 can include a single metal layer, while the redistribution structure 224 can include multiple metal layers (e.g., two, three, four, five, or more layers). The redistribution structure 224 can be thicker than the routing structure 214 (e.g., the thickness of the redistribution structure 224 can be at least 110%, 120%, 150%, 200%, 300%, 400%, or 500% of the thickness of the routing structure 214). In some embodiments, during operation of the device 200, the redistribution structure 224 generates more heat (e.g., due to Joule heating) than the routing structure 214 and/or the intermediate structure 212 of the first die assembly 204a. For example, the total amount of heat generated by the redistribution structure 224 during operation can be at least 110%, 120%, 150%, 200%, 300%, 400%, or 500% of the total amount of heat generated by the routing structure 214 and/or the intermediate structure 212.

A second insulating material 226 (e.g., an electrically insulating material) can be coupled to the redistribution structure 224. The second insulating material 226 can be a passivation material, such as a dielectric material, a polyimide material, and/or other materials used to cover a surface of a semiconductor device. In some embodiments, the second insulating material 226 includes apertures formed therein (not shown) to expose the bond pads of the redistribution structure 224 for coupling to external electrical connectors (e.g., wire bonds, micro-bumps, solder bumps, pillars, etc.), as discussed in greater detail below.

The second die assembly 204b further includes a second set of vias or interconnections 228 (“second vias 228”) extending from the redistribution structure 224 through the entire thickness of the carrier substrate 220 to the second surface 222b. The second vias 228 can include TSVs and/or other types of electrically conductive interconnections. The second vias 228 can be used to route signals between the second die assembly 204b and the first die assembly 204a, as described further below.

The first and second die assemblies 204a-b are connected to each other by the thermal buffer structure 202. In the illustrated embodiment, the thermal buffer structure 202 is coupled to the second surface 208b of the semiconductor substrate 206 and the second surface 222b of the carrier substrate 220, such that the first and second die assemblies 204a-b are arranged in a “back-to-back” configuration with the thermal buffer structure 202 in between. To reduce or prevent heat transfer between the first and second die assemblies 204a-b, the thermal buffer structure 202 can have a thermal conductivity that is less than the thermal conductivity of the semiconductor substrate 206 and/or the carrier substrate 220. For example, the thermal conductivity of the thermal buffer structure 202 can be no more than 90%, 80%, 70%, 60%, 50%, 40%, 30%, 20%, 10%, 5%, 1%, 0.25%, or 0.1% of the thermal conductivity of the semiconductor substrate 206 and/or the carrier substrate 220. In some embodiments, the thermal conductivity of the thermal buffer structure 202 is less than or equal to 50 W/mK, 40 W/mK, 30 W/mK, 20 W/mK, 10 W/mK, 5 W/mK, 1 W/mK, 0.5 W/mK, or 0.1 W/mK. The thermal conductivity of the semiconductor substrate 206 and/or the carrier substrate 220 can be greater than or equal to 50 W/mK, 75 W/mK, 100 W/mK, 125 W/mK, or 150 W/mK. Accordingly, the presence of the thermal buffer structure 202 between the first and second die assemblies 204a-b can physically separate and thermally isolate heat-generating components (e.g., the redistribution structure 224) from temperature-sensitive components (e.g., the active circuit elements 210). For example, in some embodiments, the device 200 is a memory device (e.g., NAND, DRAM, NOR, etc.), the active circuit elements 210 include CMOS circuitry, and the intermediate structure 212 includes a memory array. In such embodiments, the performance and reliability of the memory device can be improved by separating the redistribution structure 224 from the CMOS circuitry and memory array.

The thermal buffer structure 202 can define a separation zone and have many different configurations. In some embodiments, for example, the thermal buffer structure 202 includes a thermally insulative material 230, such as a thermally insulative film, sheet, matrix, resin, mold compound, paste, etc. For example, the thermally insulative material 230 can be a non-conductive film (NCF), a die attach film (DAF), or an underfill material. The underfill material can be a capillary underfill material, a nonconductive epoxy paste (e.g., XS8448-171 manufactured by Namics Corporation of Niigata, Japan), a dielectric underfill (e.g., as FP4585 manufactured by Henkel of Dusseldorf, Germany), and/or other suitable materials having a low thermal conductivity. In other embodiments, however, the thermally insulative material 230 can be omitted, and the thermal buffer structure 202 can instead include an air gap between the semiconductor substrate 206 and the carrier substrate 220. The thermal buffer structure 202 can have any suitable thickness, such as a thickness within a range from 1 μm to 50 μm.

The device 200 can include a plurality of interconnect structures 232 extending through the entire thickness of the thermal buffer structure 202 to transmit signals between the first and second die assemblies 204a-b. The interconnect structure 232 can electrically couple the first vias 218 of the first die assembly 204a to the second vias 228 of the second die assembly 204b. In some embodiments, the interconnect structures 232 also mechanically couple the semiconductor substrate 206 to the carrier substrate 220 (e.g., in combination with the thermally insulative material 230). The interconnect structures 232 can include bumps, micro-bumps, pillars, columns, studs, etc. Each interconnect structure 232 can be formed of any suitably conductive material such as copper, nickel, gold, silicon, tungsten, solder (e.g., SnAg-based solder), conductive-epoxy, combinations thereof, etc., and can be formed by electroplating, electroless-plating, or another suitable process. Optionally, the interconnect structures 232 can also include barrier materials (e.g., nickel, nickel-based intermetallic, and/or gold) formed over end portions of the interconnect structures 232. The barrier materials can facilitate bonding and/or prevent or at least inhibit the electromigration of copper or other metals used to form the interconnect structures 232.

For example, in the illustrated embodiment, each interconnect structure 232 includes a first pillar element 234a (e.g., a first copper pillar) coupled to the second surface 208b of the semiconductor substrate 206 at the locations of the first vias 218, a second pillar element 234b (e.g., a second copper pillar) coupled to the second surface 222b of the carrier substrate 220 at the locations of the second vias 228, and a solder bump 236 or other electrically conductive connector electrically and mechanically connecting the first and second pillar elements 234a-b. In other embodiments, however, other types of interconnect structures and materials can be used.

During operation of the device 200, signals from the active circuit elements 210 can be transmitted through the intermediate structure 212 to the routing structure 214, which routes the signals to the first vias 218. Subsequently, the signals can be transmitted sequentially through the first vias 218, interconnect structures 232, and second vias 228 to reach the redistribution structure 224. The redistribution structure 224 can route the signals to an external device (e.g., another semiconductor die or a package substrate; not shown in FIG. 2A). Conversely, signals from the external device can be transmitted to the redistribution structure 224, which routes the signals to the second vias 228. The signals can then be transmitted sequentially through the second vias 228, interconnect structures 232, and first vias 218 to the routing structure 214. The routing structure 214 can route signals to the intermediate structure 212 and the active circuit elements 210.

FIG. 2B is a schematic side cross-sectional view of the first die assembly 204a during a manufacturing process, in accordance with embodiments of the present technology. The manufacturing process can be a wafer level or die level process, and can involve sequentially forming the individual layers of the first die assembly 204a using semiconductor manufacturing techniques known to those of skill in the art. For example, the active circuit elements 210 can be formed in and/or on the first surface 208a of the semiconductor substrate 206, and then the intermediate structure 212 is formed over the active circuit elements. In general, the active circuit elements 210 and/or the intermediate structure are formed using FEOL processing techniques. The first vias 218 can then be formed through the semiconductor substrate 206, the active circuit elements 210, and the intermediate structure 212. In some embodiments, the routing structure 214 can then be formed on the intermediate structure 212 and electrically connected to the first vias 218. In other embodiments, the routing structure 214 can be formed on the intermediate structure 212 before forming the vias 218. The first insulating material 216 is then applied to the routing structure 214.

FIG. 2C is a schematic side cross-sectional view of the second die assembly 204b during a manufacturing process in accordance with embodiments of the present technology. The manufacturing process for the second die assembly 204b can also be performed at either the wafer level or the die level, and can involve sequentially forming the individual layers of the second die assembly 204b using semiconductor manufacturing techniques known to those of skill in the art. For example, in some embodiments the second vias 228 are formed in the carrier substrate 220 and then the redistribution structure 224 is formed on the first surface 222a of the carrier substrate 220 and electrically coupled to the second vias 228. In other embodiments, the redistribution structure 224 is formed on the first surface 222a of the carrier substrate 220 and then the second vias 228 are formed through the carrier substrate 220. The redistribution structure 224 can be formed using BEOL processing techniques. Subsequently, the second insulating material 226 can be applied to the redistribution structure 224.

Referring again to FIG. 2A, to assemble the device 200, the first and second die assemblies 204a-b are mechanically and electrically coupled to each other via the thermal buffer structure 202. In some embodiments, the thermal buffer structure 202 is formed in situ between the first and second die assemblies 204a-b after the first and second pillar elements 234a-b have been connected together, such that the first and second die assemblies 204a-b are coupled to each other and to the thermal buffer structure 202 during the process of forming the thermal buffer structure 202. In other embodiments, however, the thermal buffer structure 202 can be a pre-formed component that is coupled to at least one of the first and second die assemblies 204a-b before the first and second pillar elements 234a-b have been connected together.

The thermal buffer structure 202 can be formed in many different ways, such as using die attach methods known to those of skill in the art (e.g., direct chip attach, micro-bumping, etc.). In some embodiments, for example, the first pillar elements 234a are coupled to the first die assembly 204a (e.g., to the first vias 218 at the second surface 208b of the semiconductor substrate 206), and the second pillar elements 234b are coupled to the second die assembly 204b (e.g., to the second vias 228 at the second surface 220b of the carrier substrate 220). The first and second pillar elements 234a-b can subsequently be electrically and mechanically coupled to each other via the solder bumps 236 to form the interconnect structures 232, e.g., using a thermocompression bonding (TCB) or mass reflow operation. To form the thermal buffer structure 202, the thermally insulative material 230 can be positioned between the first and second die assemblies 204a-b before and/or during the TCB/mass reflow operation (e.g., in embodiments where the thermally insulative material 230 is a solid material such as an NCF or DAF), or after the TCB/mass reflow operation (e.g., in embodiments where the thermally insulative material 230 is a flowable material such as a capillary underfill material). Accordingly, the first and second die assemblies 204a-b can be electrically and mechanically joined to each other via the interconnect structures 232 and thermally insulative material 230.

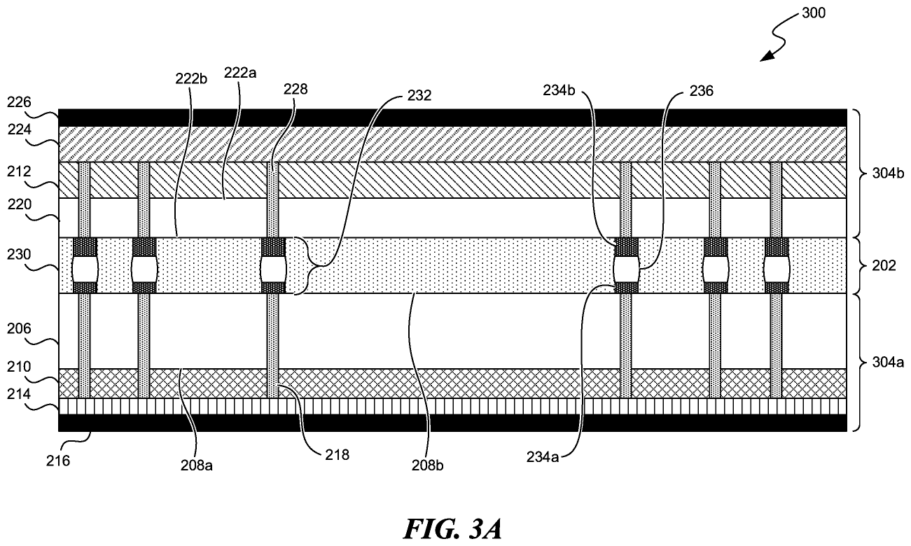

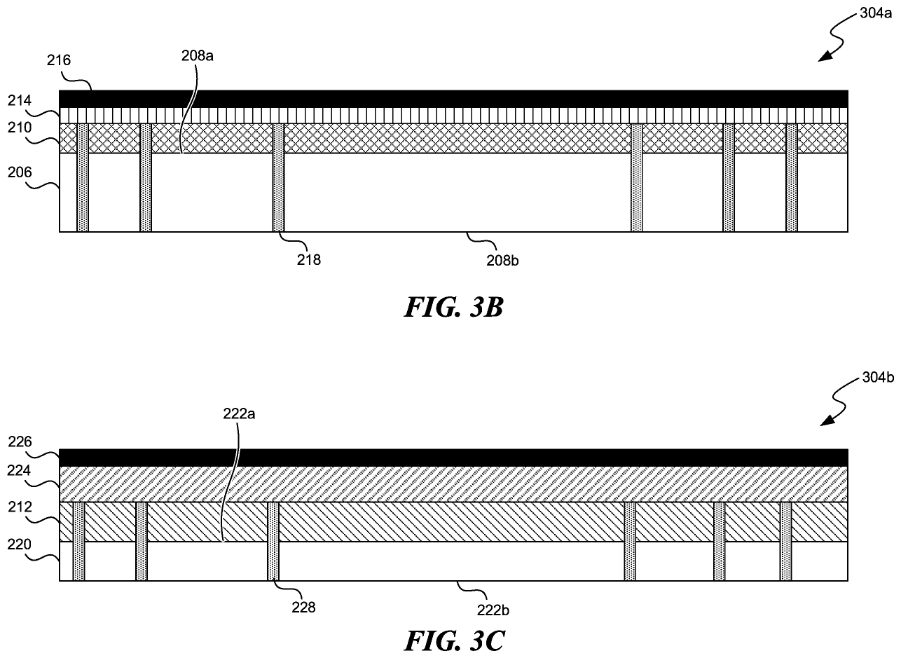

FIG. 3A is a schematic side cross-sectional view of a semiconductor device 300 including a thermal buffer structure 202 configured in accordance with embodiments of the present technology. The device 300 can be generally similar to the device 200 described with respect to FIGS. 2A-2C. Accordingly, like numbers are used to identify similar or identical components, and discussion of the device 300 of FIG. 3A will be limited to those features that differ from the device 200.

The device 300 includes a first die assembly 304a and a second die assembly 304b connected to each other by the thermal buffer structure 202. The first die assembly 304a of the device 300 includes a semiconductor substrate 206, a plurality of active circuit elements 210 formed in and/or on the first surface 208a of the semiconductor substrate 206, a routing structure 214 coupled to the active circuit elements 210, and a first insulating material 216 coupled to the routing structure 214. In the illustrated embodiment, the first die assembly 304a does not include any intermediate structures (e.g., MOL structures) between the active circuit elements 210 and the routing structure 214, such that the routing structure 214 is directly connected to the active circuit elements 210. The first die assembly 304a can further include first vias 218 extending from the second surface 208b through the semiconductor substrate 206 and active circuit elements 210 to the routing structure 214. In other embodiments, the routing structure 214 can be omitted, such that the first vias 218 are electrically coupled directly to the active circuit elements 210 and terminate at or near the first surface 208a of the semiconductor substrate 206.

The second die assembly 304b of the device 300 includes a carrier substrate 220, an intermediate structure 212 coupled to the first surface 222a of the carrier substrate 220, a redistribution structure 224 coupled to the intermediate structure 212, and a second insulating material 226. The second die assembly 304b can also include second vias 228 extending through the entire thickness of the carrier substrate 220 and the intermediate structure 212 such that they are electrically coupled to the redistribution structure 224. The second vias 228 can be connected to the first vias 218 of the first die assembly 304a by interconnect structures 232 extending through the thermal buffer structure 302.

The configuration of the device 300 illustrated in FIG. 3A can further reduce the amount of heat transmitted to the active circuit elements 210 by thermally isolating the active circuit elements 210 from both the intermediate structure 212 and the redistribution structure 224. For example, in some embodiments, the device 300 is a memory device (e.g., NAND, DRAM, NOR, etc.), the active circuit elements 210 include CMOS circuitry, and the intermediate structure 212 includes a memory array. In such embodiments, the separation between the memory array and the CMOS circuitry can further improve performance and reliability of the memory device.

FIG. 3B is a schematic side cross-sectional view of the first die assembly 304a during a manufacturing process in accordance with embodiments of the present technology. The process for manufacturing the first die assembly 304a can be similar to the process described with respect to FIG. 2B, except that the routing structure 214 is formed directly on the active circuit elements 210, rather than on an intermediate structure.

FIG. 3C is a schematic side cross-sectional view of the second die assembly 304b during a manufacturing process in accordance with embodiments of the present technology. The process for manufacturing the second die assembly 304b can be similar to the process described with respect to FIG. 2C, except that the intermediate structure 212 is formed on the first surface 222a of the carrier substrate 220, and the redistribution structure 224 can be formed on the intermediate structure 212.

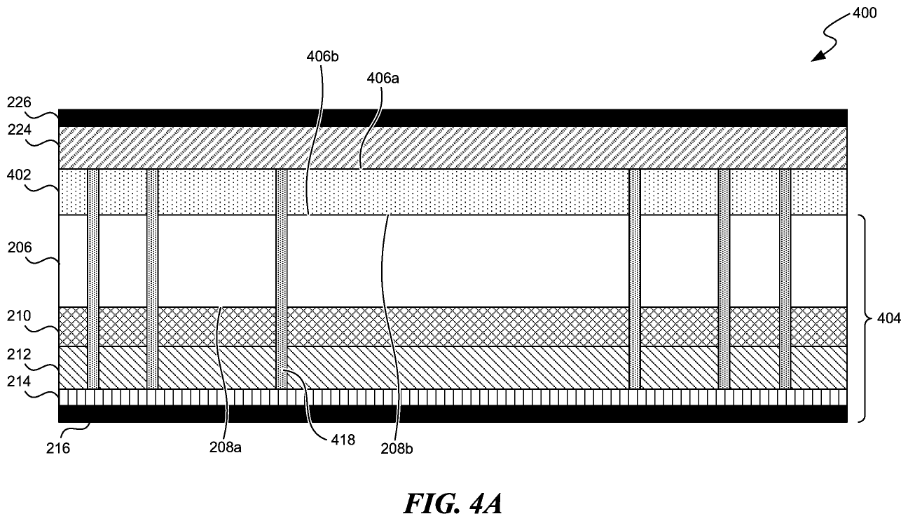

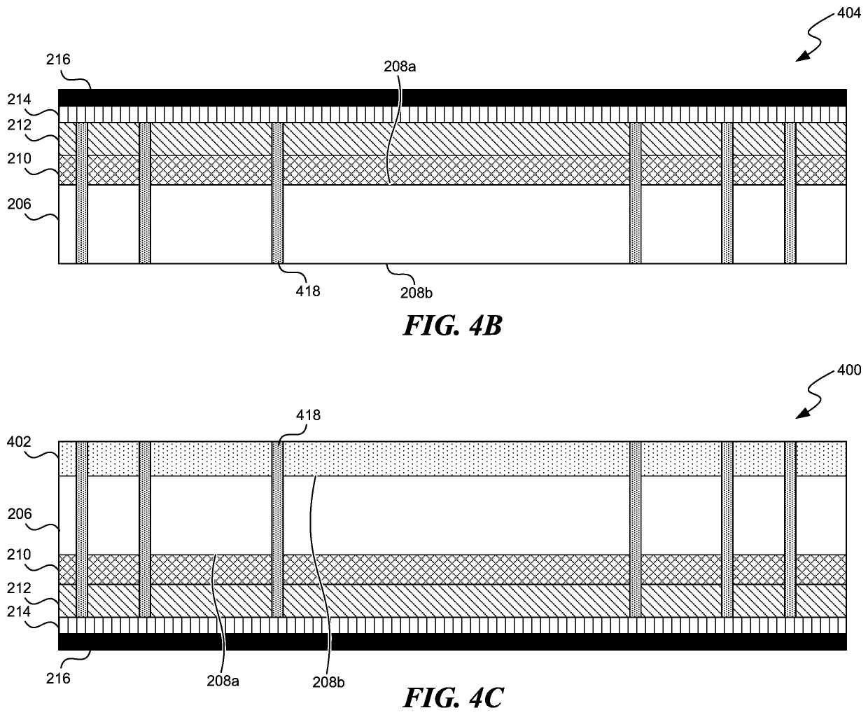

FIG. 4A is a schematic side cross-sectional view of a semiconductor device 400 including a thermal buffer structure 402 configured in accordance with embodiments of the present technology. In contrast to the devices 200, 300 of FIGS. 2A-3C, the device 400 does not include a separate carrier substrate or a second die assembly. Instead, the thermal buffer structure 402 is used both for thermal isolation and as a substrate for fabricating the redistribution structure 224, as discussed in detail below. The configuration of the device 400 shown in FIG. 4A can advantageously reduce the overall device size and can also simplify the manufacturing process.

The device 400 includes a die assembly 404, which may be identical or generally similar to the first die assembly 204a of FIGS. 2A-2B and/or the first die assembly 304a of FIGS. 3A-3B. For example, the die assembly 404 can include a semiconductor substrate 206 with a first surface 208a and a second surface 208b, a plurality of active circuit elements 210 formed in and/or on the first surface 208a, an intermediate structure 212 coupled to the active circuit elements 210, a routing structure 214 coupled to the intermediate structure 212, and a first insulating material 216 coupled to the routing structure 214. In other embodiments, the intermediate structure 212 and/or routing structure 214 are optional and can be omitted.

The thermal buffer structure 402 includes a first surface 406a (e.g., a front or active surface) and a second surface 406b (e.g., a back surface). The second surface 406b of the thermal buffer structure 402 can be directly coupled to the second surface 208a of the semiconductor substrate 206. A redistribution structure 224 can be coupled to the first surface 406a of the thermal buffer structure 402, and a second insulating material can be coupled to the redistribution structure 224. In the illustrated embodiment, the redistribution structure 224 is coupled directly to the thermal buffer structure 402. In other embodiments, however, the device 400 can include one or more additional structures between the redistribution structure 224 and the thermal buffer structure 402 (e.g., an intermediate structure such as a memory array, as previously described with respect to FIGS. 3A-3C).

The thermal buffer structure 402 can physically separate and thermally isolate temperature-sensitive components of the die assembly 404 (e.g., the active circuit elements 210) from heat-generating components on the first surface 406a of the thermal buffer structure 402 (e.g., the redistribution structure 224). For example, to reduce or prevent heat transfer through the thermal buffer structure 402, the thermal buffer structure 402 can have a thermal conductivity that is less than the thermal conductivity of the semiconductor substrate 206. In some embodiments, the thermal conductivity of the thermal buffer structure 402 is no more than 90%, 80%, 70%, 60%, 50%, 40%, 30%, 20%, 10%, or 5% of the thermal conductivity of the semiconductor substrate 206. The thermal buffer structure 402 can be made of a thermally insulative material that is also suitable for use as a substrate upon which the redistribution structure 224 can be formed or otherwise attached. For example, the thermal buffer structure 402 can be made of a mold material having a low thermal conductivity, such as an epoxy mold compound or resin. The thermal buffer structure 402 can have any suitable thickness, such as a thickness within a range from 10 μm to 50 μm.

The device 400 can include a set of vias or interconnections 418 (e.g., TSVs) electrically coupling the routing structure 214 to the redistribution structure 224 to transmit signals between the die assembly 404 and the components on the first surface 406a of the thermal buffer structure 402. As shown in FIG. 4A, the vias 418 can extend through the entire thickness of the thermal buffer structure 402, semiconductor substrate 206, active circuit elements 210, and intermediate structure 212. During operation of the device 400, signals from the active circuit elements 210 can be sequentially transmitted through the intermediate structure 212, routing structure 214, and vias 418 to the redistribution structure 224. The redistribution structure 224 can subsequently route the signals to an external device (not shown). Conversely, signals from the external device can be routed by the redistribution structure 224 to the vias 418, and subsequently transmitted through routing structure 214 and intermediate structure 212 to the active circuit elements 210.

FIG. 4B is a schematic side cross-sectional view of the die assembly 404 after a stage of a manufacturing process, in accordance with embodiments of the present technology. The process for manufacturing the die assembly 404 can be identical or generally similar to the processes described with respect to FIGS. 2B and 3B. For example, the process can involve sequentially forming the active circuit elements 210, intermediate structure 212, routing structure 214, and first insulating material 216 on the first surface 208a of the semiconductor substrate 206. The vias 418 can then be formed through the substrate 206, active circuit elements 210, and intermediate structure 214.

FIG. 4C is a schematic side cross-sectional view of the device 400 after a subsequent stage of the manufacturing process, in accordance with embodiments of the present technology. After the die assembly 404 has been manufactured, the thermal buffer structure 402 can be coupled to and/or formed on the second surface 208a of the semiconductor substrate 206 (e.g., by molding, bonding, deposition, etc.) and the vias 418 can be extended through the thermal buffer structure 402. In other embodiments, the thermal buffer structure 402 can be formed on the second surface 208b of the substrate 206 before any portion of the vias 418 are formed through the substrate 206, active circuit elements 210, intermediate structure 214, or thermal buffer structure 402. The vias 418 can then be formed through the substrate 206, active circuit elements 210, intermediate structure 214, and thermal buffer structure 402 to be electrically coupled to the routing structure 214. Subsequently, additional device components (e.g., the redistribution structure 424 and second insulating material 426 (FIG. 4A)) can be sequentially formed on the first surface 406a of the thermal buffer structure 402.

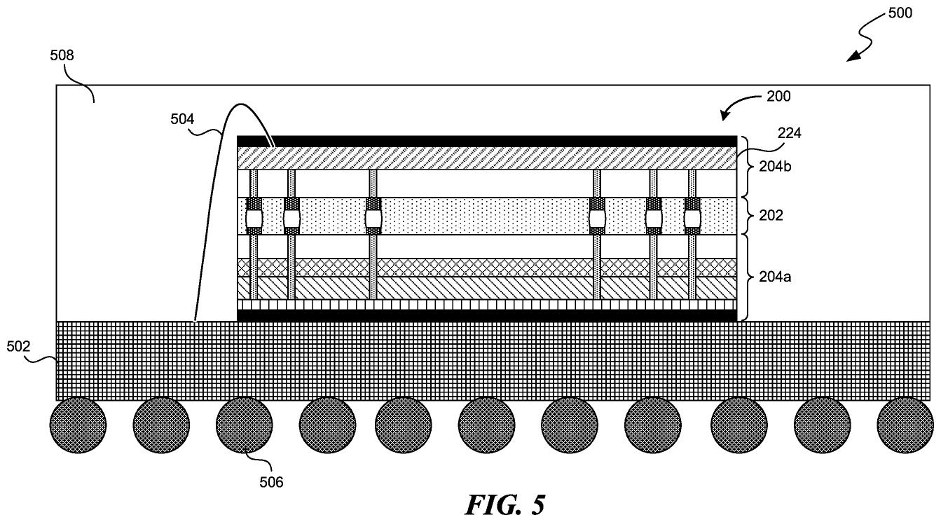

FIGS. 5-9 illustrate various semiconductor packages configured in accordance with embodiments of the present technology. Although the semiconductor packages of FIGS. 5-9 are depicted as incorporating semiconductor devices identical or similar to the device 200 of FIG. 2A, in other embodiments, the semiconductor packages of FIGS. 5-9 can include any of the other semiconductor devices described herein with respect to FIGS. 2A-4C.

FIG. 5 is a schematic side cross-sectional view of a semiconductor package 500 configured in accordance with embodiments of the present technology. The package 500 includes a semiconductor device (e.g., device 200 of FIGS. 2A-2C) mounted on a package substrate 502. The package substrate 502 can be or include an interposer, a printed circuit board, a dielectric spacer, another semiconductor die (e.g., a logic die), or another suitable substrate. Optionally, the package substrate 502 can include semiconductor components (e.g., doped silicon wafers or gallium arsenide wafers), nonconductive components (e.g., various ceramic substrates, such as aluminum oxide (Al₂O₃), etc.), aluminum nitride, and/or conductive portions (e.g., interconnecting circuitry, TSVs, etc.).

In the illustrated embodiment, the device 200 is mounted to the package substrate 502 such that the first die assembly 204a is adjacent or near the package substrate 502, the second die assembly 204b is spaced apart from the package substrate 502, and the redistribution structure 224 oriented upward and away from the package substrate 502 (also referred to herein as a “BEOL up” configuration). The device 200 can be mechanically coupled to the package substrate 502 using any suitable die-to-substrate attachment process known to those of skill in the art. To allow for signal transmission between the device 200 and the package substrate 502, the device 200 can be electrically coupled to the package substrate 502 by one or more wirebonds 504 electrically coupling the redistribution structure 224 to the package substrate 502. The package substrate 502 can further include an array of electrical connectors 506 (e.g., solder balls, conductive bumps, conductive pillars, conductive epoxies, and/or other suitable electrically conductive elements) electrically coupled to the package substrate 502 and configured to electrically couple the package 500 to external devices or circuitry (not shown).

The package 500 can include a mold material 508, such as a resin, epoxy resin, silicone-based material, polyimide, or any other material suitable for encapsulating the device 200 and/or at least a portion of the package substrate 502 to protect these components from contaminants and/or physical damage. The package 500 can also include other components such as external heatsinks, a casing (e.g., thermally conductive casing), electromagnetic interference (EMI) shielding components, etc.

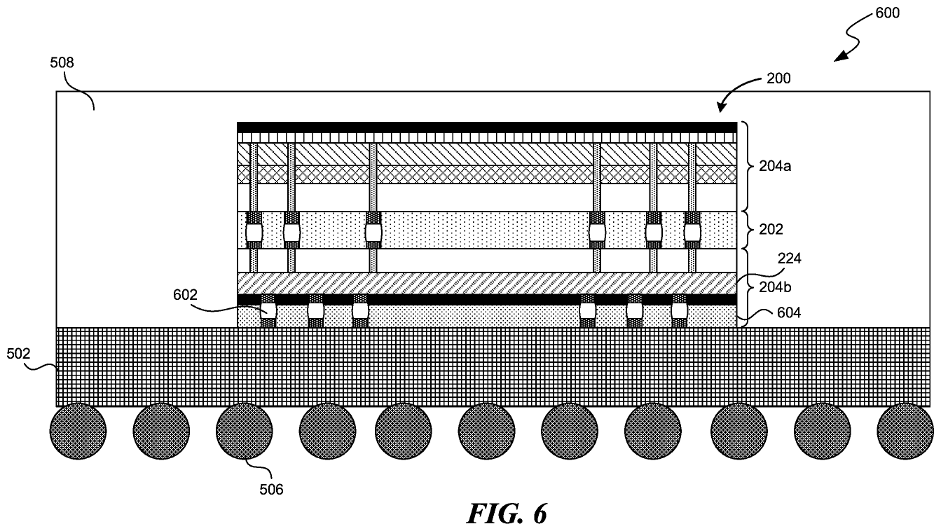

FIG. 6 is a schematic side cross-sectional view of a semiconductor package 600 configured in accordance with embodiments of the present technology. The package 600 is generally similar to the package 500 of FIG. 5, except that the device 200 is mounted to the package substrate 502 such that the first die assembly 204a is spaced apart from the package substrate 502, the second die assembly 204b is near the package substrate 502, and the redistribution structure 224 is oriented downward and toward from the package substrate 502 (also referred to herein as a “BEOL down” configuration). The device 200 can be electrically coupled to the package substrate 502 by a plurality of interconnect structures 602 (e.g., copper pillars or other electrically conductive bumps, micro-bumps, pillars, columns, studs, etc.) to transmit signals between the device 200 and the package substrate 502. The interconnect structures 602 can be surrounded by an underfill material 604 (e.g., a capillary underfill material).

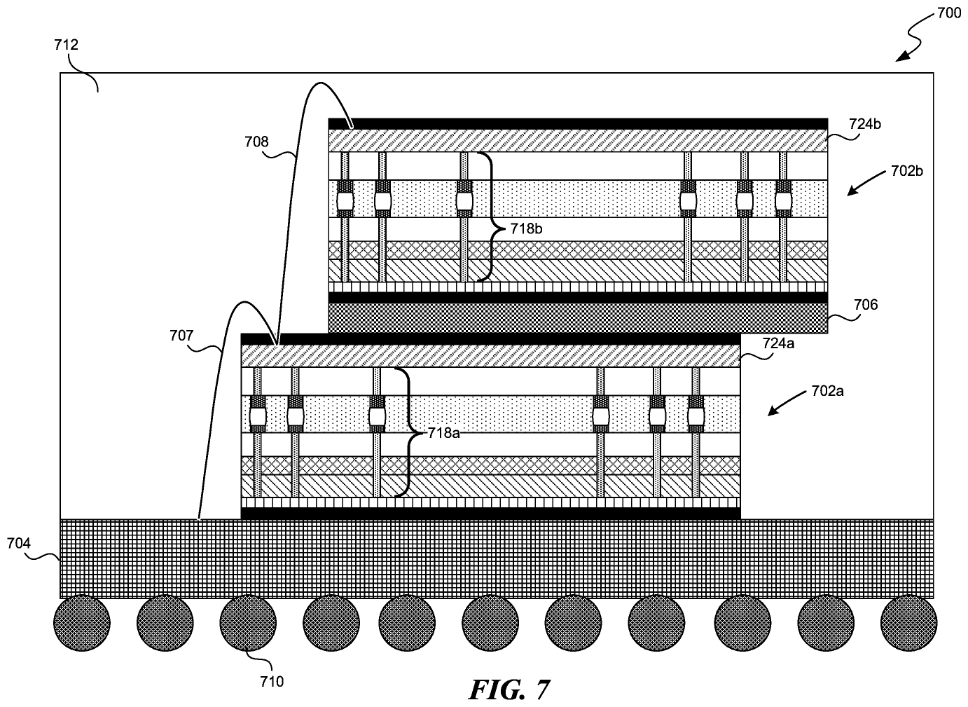

FIG. 7 is a schematic side cross-sectional view of a semiconductor package 700 configured in accordance with embodiments of the present technology. The package 700 includes a first semiconductor device 702a and a second semiconductor device 702b supported by a package substrate 704. The first and second devices 702a-b are vertically arranged in a stack with the first device 702a mounted on the package substrate 704 (e.g., using die-to-substrate attachment techniques), and the second device 702b mounted on the first device 702a (e.g., via a DAF 706 or other die-to-die attachment techniques). Although FIG. 7 illustrates two stacked devices, in other embodiments the package 700 can include any number of stacked devices (e.g., three, four, five, six, seven, eight, nine, ten, or more devices). Additionally, although the first and second devices 702a-b are both shown as having a configuration similar to the device 200 of FIGS. 2A-2C, in other embodiments, any of the devices 702a-b can have a different configuration (e.g., a configuration similar to the devices 300, 400 of FIGS. 3A-4C).

In the illustrated embodiment, the first and second devices 702a-b are both oriented in the same direction (BEOL up) with their respective redistribution structures 724a, 724b facing upward and away from the package substrate 704. Signals can be transmitted between the first device 702 and the package substrate 704 via a first set of wirebonds 707 electrically coupling the redistribution structure 724a of the first device 702 to the package substrate 704. Similarly, signals can be transmitted between the first and second devices 702a-b via a second set of wirebonds 708 electrically coupling the redistribution structure 724b of the second device 702b to the redistribution structure 724a of the first device 702a. Optionally, the package 700 can include one or more wirebonds (not shown) directly connecting the redistribution structure 724b of the second device 702b to the package substrate 704. Accordingly, signals can be routed between the first device 702a, second device 702b, and/or package substrate 704 via the wirebonds 707, 708 and the respective redistribution structures 724a-b and internal interconnections 718a-b of the first and second devices 702a-b.

The package 700 can also include additional semiconductor packaging components such as an array of electrical connectors 710 and a mold material 712 encapsulating the first and second devices 702a-b. The package substrate 704, electrical connectors 710, and mold material 712 can be identical or generally similar to the corresponding components discussed above with respect to FIG. 5.

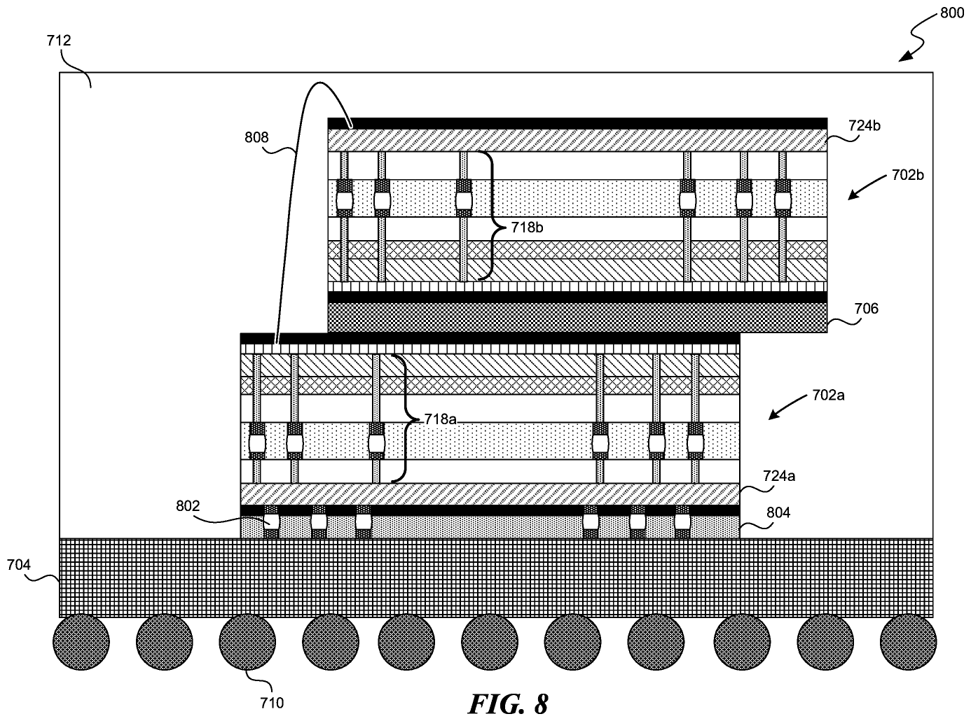

FIG. 8 is a schematic side cross-sectional view of a semiconductor package 800 configured in accordance with embodiments of the present technology. The package 800 is generally similar to the package 700 of FIG. 7, except that the first device 702a is oriented in a different direction than the second device 702b. In the illustrated embodiment, for example, the redistribution structure 724a of the first device 702a faces downward (BEOL down) and toward the package substrate 704, while the redistribution structure 724b of the second device 702b faces upward and away from the package substrate 704 (BEOL up).

The first device 702a can be electrically and mechanically coupled to the package substrate 704 via a plurality of interconnect structures 802 and an underfill material 804 (e.g., as previously discussed with respect to FIG. 6) to allow for signal routing between the first device 702a and the package substrate 704. The interconnect structures 802 and underfill material 804 can be formed using any suitable process, such as a TCB/mass reflow operation. The redistribution structure 724b of the second device 702b can be electrically connected to the redistribution structure 724a of the first device 702a via a set of wirebonds 808 to transmit signals between the first and second devices 702a-b. Optionally, the package 800 can include one or more wirebonds (not shown) electrically coupling the redistribution structure 724b of the second device 702b directly to the package substrate 704. Accordingly, signals can be routed between the first device 702a, second device 702b, and/or package substrate 704 via the interconnect structures 802, wirebonds 808, and the respective redistribution structures 724a-b and internal interconnections 718a-b of the first and second devices 702a-b.

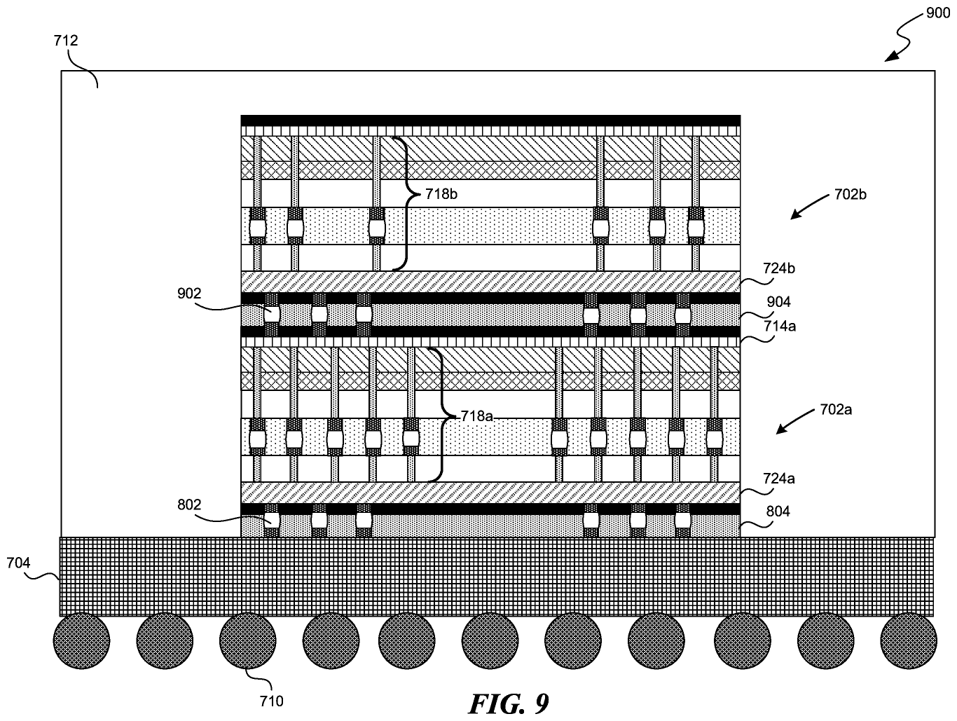

FIG. 9 is a schematic side cross-sectional view of a semiconductor package 900 configured in accordance with embodiments of the present technology. The package 900 is generally similar to the package 800 of FIG. 8, except that the first and second devices 702a-b are both oriented with their respective redistribution structures 724a-b facing downward and toward the package substrate 704 (BEOL down). Similar to the package 800 of FIG. 8, the first device 702a is electrically and mechanically coupled to the package substrate 704 via a plurality of interconnect structures 802 and an underfill material 804 between the redistribution structure 724a and the package substrate 704.

The redistribution structure 724b of the second device 702b can be electrically and mechanically coupled to the first device 702a (e.g., to routing structure 714a) via a plurality of interconnect structures 902 and an underfill material 904. The interconnect structures 902 and underfill material 904 can be formed using any suitable process, such as a TCB/mass reflow operation. Accordingly, signals can be routed between the first device 702a, second device 702b, and/or package substrate 704 via the interconnect structures 802, 902, the routing structure 714a, and the respective redistribution structures 724a-b and internal interconnections 718a, 718b of the first and second devices 702a, 702b. In some embodiments, the first device 702a includes more internal interconnections 718a than the second device 702b, e.g., to accommodate signal routing between the second device 702b and the package substrate 704.

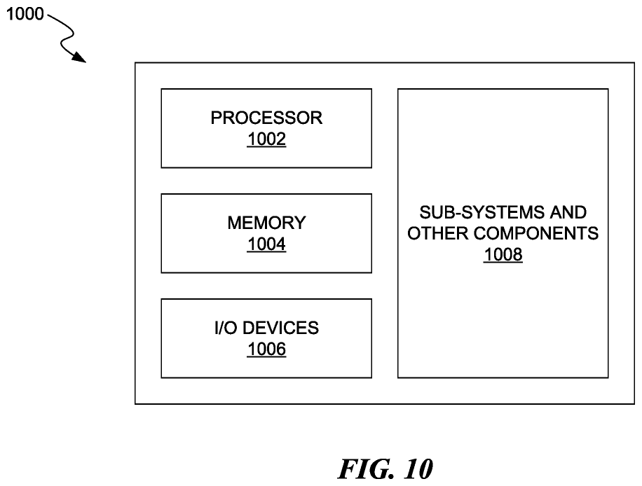

Any one of the semiconductor devices and/or packages having the features described above with reference to FIGS. 2A-9 can be incorporated into any of a myriad of larger and/or more complex systems, a representative example of which is system 1000 shown schematically in FIG. 10. The system 1000 can include a processor 1002, a memory 1004 (e.g., SRAM, DRAM, flash, and/or other memory devices), input/output devices 1006, and/or other subsystems or components 1008. The semiconductor dies and/or packages described above with reference to FIGS. 2A-9 can be included in any of the elements shown in FIG. 10. The resulting system 1000 can be configured to perform any of a wide variety of suitable computing, processing, storage, sensing, imaging, and/or other functions. Accordingly, representative examples of the system 1000 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 1000 include lights, cameras, vehicles, etc. With regard to these and other example, the system 1000 can be housed in a single unit or distributed over multiple interconnected units, e.g., through a communication network. The components of the system 1000 can accordingly include local and/or remote memory storage devices and any of a wide variety of suitable computer-readable media.

From the foregoing, it will be appreciated that specific embodiments of the technology have been described herein for purposes of illustration, but that various modifications may be made without deviating from the disclosure. Accordingly, the invention is not limited except as by the appended claims. Furthermore, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

I/We claim:

1. A semiconductor device, comprising:
a first die assembly including—
a semiconductor substrate including a first surface and a second surface opposite the first surface, and
a plurality of active circuit elements at the first surface of the semiconductor substrate;
a second die assembly including—
a carrier substrate including a first surface and a second surface opposite the first surface, and
a redistribution structure on or over the first surface of the carrier substrate;
a thermal buffer structure between the first and second die assemblies, wherein the thermal buffer structure is coupled to the second surface of the semiconductor substrate and the second surface of the carrier substrate; and
a plurality of interconnections extending through at least the semiconductor substrate, the carrier substrate, and the thermal buffer structure, wherein the interconnections electrically couple the active circuit elements to the redistribution structure.

2. The semiconductor device of claim 1 wherein the thermal buffer structure is less thermally conductive than the semiconductor substrate.

3. The semiconductor device of claim 1 wherein the thermal buffer structure comprises an underfill material, a non-conductive film, or a die attach film.

4. The semiconductor device of claim 1 wherein the redistribution structure is configured to route signals between the active circuit elements and an external device.

5. The semiconductor device of claim 1 wherein the redistribution structure is directly coupled to the carrier substrate.

6. The semiconductor device of claim 1 wherein the second die assembly further comprises at least one intermediate structure between the redistribution structure and the carrier substrate.

7. The semiconductor device of claim 6 wherein the at least one intermediate structure comprises a memory array.

8. The semiconductor device of claim 1 wherein:
the first die assembly further comprises a routing structure adjacent or near the active circuit elements; and
the interconnections electrically couple the redistribution structure to the active circuit elements via the routing structure.

9. The semiconductor device of claim 8 wherein the routing structure is thinner than the redistribution structure.

10. The semiconductor device of claim 8 wherein the first die assembly further comprises at least one intermediate structure between the active circuit elements and the routing structure.

11. The semiconductor device of claim 10 wherein the at least one intermediate structure comprises a memory array.

12. The semiconductor device of claim 1 wherein the interconnections include: (a) a plurality of first vias extending through the semiconductor substrate, (b) a plurality of second vias extending through the carrier substrate, and (c) a plurality of interconnect structures extending through the thermal buffer structure.

13. A method of manufacturing a semiconductor device, the method comprising:
forming a first die assembly including—
a semiconductor substrate including a first surface and a second surface opposite the first surface, and
a plurality of active circuit elements at the first surface of the semiconductor substrate;
forming a second die assembly including—
a carrier substrate including a first surface and a second surface opposite the first surface, and
a redistribution structure on or over the first surface of the carrier substrate;
positioning a thermal buffer structure between the first and second die assemblies, wherein the thermal buffer structure is coupled to the second surface of the semiconductor substrate and the second surface of the carrier substrate;
electrically coupling the active circuit elements to a redistribution structure via a plurality of interconnections extending through at least the semiconductor substrate, the carrier substrate, and the thermal buffer structure.

14. The method of claim 13 wherein the thermal buffer structure is configured to reduce heat transmission from the redistribution structure to the active circuit elements.

15. The method of claim 13 wherein:
forming the first die assembly includes forming a first set of vias through the semiconductor substrate;
forming the second die assembly includes forming a second set of vias through the carrier structure; and
electrically coupling the active circuit elements to the redistribution structure includes connecting the first set of vias to the second set of vias using a plurality of interconnect structures extending through the thermal buffer structure.

16. The method of claim 13 wherein forming the second die assembly includes:
forming an intermediate structure on the carrier substrate; and
forming the redistribution structure on the intermediate structure.

17. The method of claim 13 wherein forming the first die assembly includes forming an intermediate structure on the active circuit elements.

18. The method of claim 13, further comprising electrically coupling the redistribution structure to a package substrate or to another semiconductor device.

19. A semiconductor device, comprising:
a semiconductor substrate including a first surface and a second surface opposite the first surface;
a plurality of active circuit elements at the first surface of the semiconductor substrate;
a thermal buffer structure including a first surface and a second surface opposite the first surface, the second surface of the thermal buffer structure being coupled to the second surface of the semiconductor substrate, wherein the thermal buffer structure comprises a mold material;
a redistribution structure on or over the first surface of the thermal buffer structure; and
a plurality of interconnections extending through at least the semiconductor substrate and the thermal buffer structure, wherein the interconnections electrically couple the active circuit elements to the redistribution structure.

20. The device of claim 19 wherein the redistribution structure is coupled directly to the first surface of the thermal buffer structure.

21. The device of claim 19, further comprising at least one intermediate structure between the redistribution structure and the thermal buffer structure.

22. The device of claim 19 wherein the thermal buffer structure is less thermally conductive than the semiconductor substrate.
